(19) United States
(12) Patent Application Publication
(10) Pub. No.: US 2024/0265155 A1
(43) Pub. Date: Aug. 8, 2024

(54) Powder House Boot Solutions

(71) Applicant: Paul Eugene Huber, Salt Lake City, UT (US)

(72) Inventor: Paul Eugene Huber, Salt Lake City, UT (US)

(21) Appl. No.: 18/640,235

(22) Filed: Apr. 19, 2024

(51) Int. Cl. G06F 30/10; B33Y 50/00; G06T 17/10

(52) U.S. Cl. CPC G06F 30/10; B33Y 50/00; G06T 17/10; G06T 2200/04

(57) ABSTRACT

Powder House Boot Solutions is a way for a skier to purchase custom fitted ski boots and footbeds off the internet. Currently, this cannot be done because the skier must be physically present. Simple photos or video recordings of the skier's lower leg and feet are taken with a smart device. These are uploaded to the Powder House Boot Solution's website. These images are then converted into 3D images and are programmed into a 3D printer or CNC robot. Either of these is used to produce replicas of the skier's lower leg and feet. These replicas are then used to shape a custom pair of ski boots and footbeds. The custom pair is then shipped to the skier, eliminating the need for them to be physically present.

### BACKGROUND OF THE INVENTION

Skiers, while on vacation, spend hours of valuable time in specialty ski shops purchasing ski boots that need to be custom fitted. The skier must be physically present for this to be accomplished. It takes time to mold, grind, punch and build custom ski boots with custom footbeds. It also takes expertise to create a custom comfortable fit. This time spent in an establishment takes away from the skier's time on the slopes, time with family, and other vacation activities. You cannot currently purchase a custom fitted ski boot on the internet because the skier's physical legs and feet have to be present. Therefore, there is a need for custom fitted ski boots to be able to be purchased off the internet, without the skier being physically present and prior to a skier going on his or her ski vacation.

### BRIEF SUMMARY OF THE INVENTION

Powder House Boot Solutions eliminates the need for a skier to be physically present to purchase custom fitted ski boots and custom fitted ski footbeds. The skier can take digital recordings with a smart device of his or her lower legs and feet and upload those images to Powder House Boot Solutions. These recordings or images are then converted by Powder House Boot Solutions into a 3D image. These 3D images are then programmed into a 3D printer or CNC robot. The 3D printer or CNC robot replicates the skier's lower legs and feet. These custom replicas are then used to heat, mold, and shape a pair of custom ski footbeds and a pair of custom fitted ski boots. Thus, the skier can purchase the complete custom pair of ski footbeds and custom fitted ski boots directly from the internet without being physically present and without having to spend valuable time in an actual ski establishment or while on their ski vacation.

### BRIEF DESCRIPTION OF THE SEVERAL VIEWS OF THE DRAWING(S)

FIG. 1 is a perspective of a person taking pictures or video of a skier's lower leg and foot of an embodiment of the disclosure of FIG. 1.

FIG. 2 is a perspective of a 3-D image of a skier's lower leg and foot of an embodiment of the disclosure of FIG. 2.

FIG. 3 is a perspective of a 3-D image of a skier's lower leg and foot converted to a CAD drawing of an embodiment of the disclosure of FIG. 3.

FIG. 4 is a perspective of a 3-D printer making a skier's replicated leg and foot of an embodiment of the disclosure of FIG. 4.

FIG. 5 is a perspective of a CNC router making a skier's replicated leg and foot an embodiment of the disclosures of FIG. 5.

FIG. 6 is a perspective of a person placing the skier's model leg and foot into a heat moldable ski boot as an embodiment of the disclosures of FIG. 6.

FIG. 7 is a perspective of a person allowing the skier's ski boot to cool to the replicated skier's lower leg and foot of the embodiment of the disclosure of FIG. 7.

FIG. 8 is a perspective of a person molding a ski footbed to the skier's replicated leg and foot of an embodiment of the disclosures of FIG. 8.

FIG. 9 is a perspective of a skier bending their knees until their heels lift as an embodiment of the disclosures of FIG. 9.

FIG. 10 is a perspective of a skier bending their knees to calculate the skier's correct stance of an embodiment of the disclosures of FIG. 10.

### DETAILED DESCRIPTION OF THE EMBODIMENT

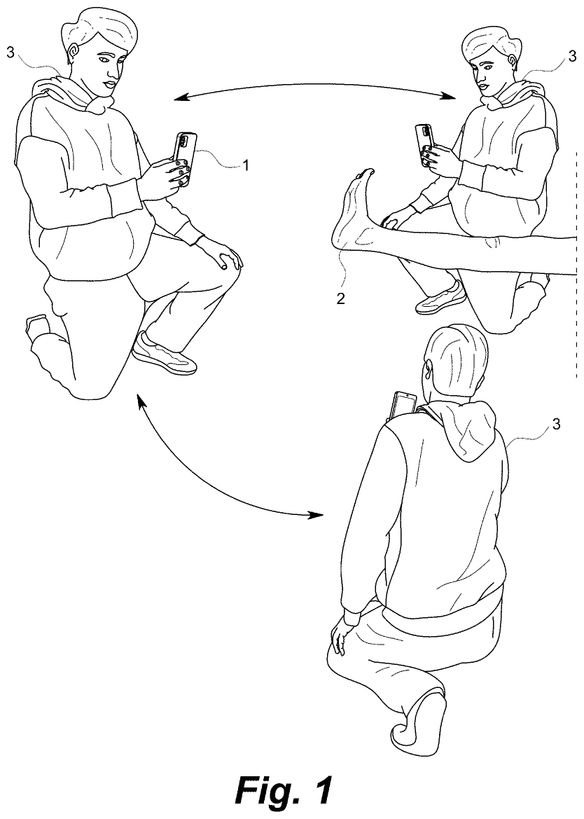

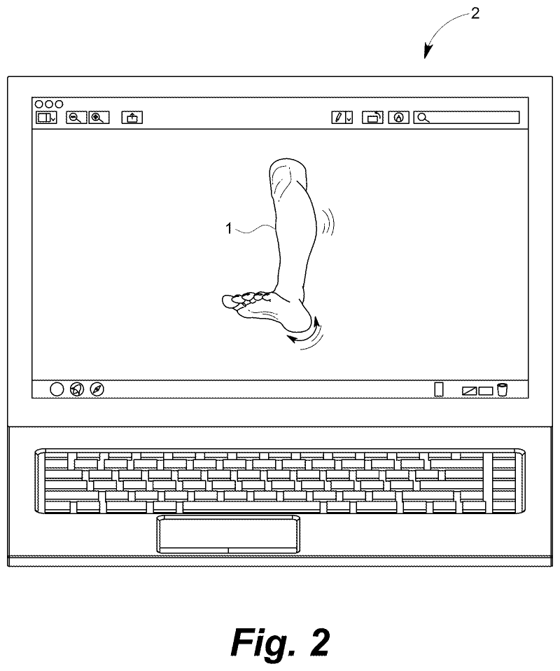

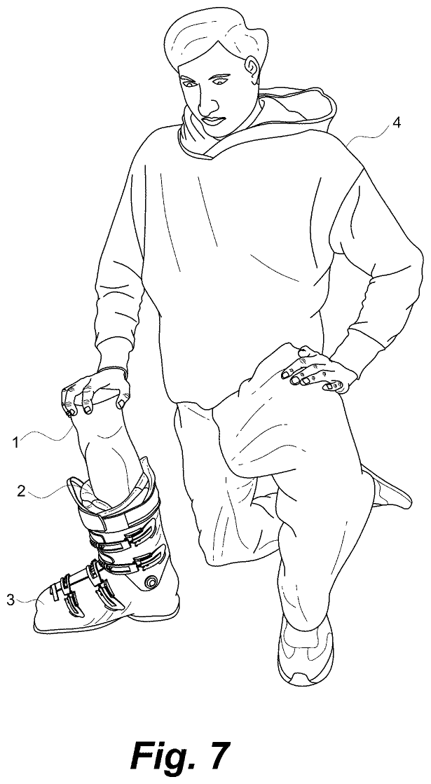

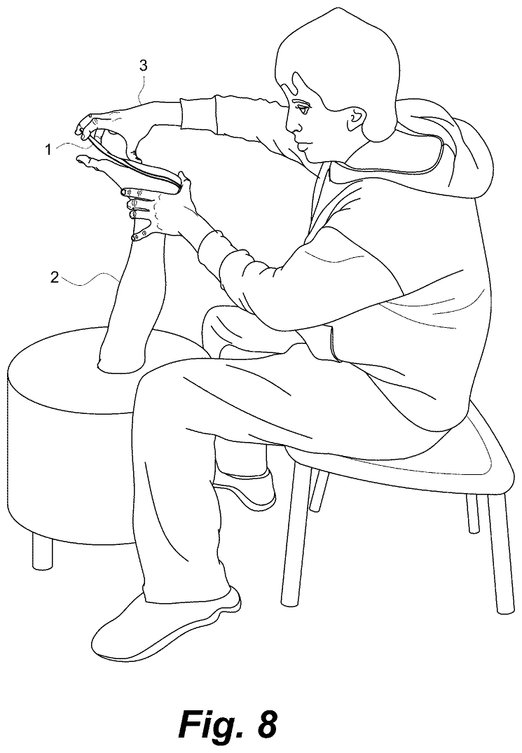

1. The invention described herein is a means for purchasing custom fitted ski boot/boots as shown in FIG. 7 (3) and custom fitted ski footbed/footbeds as shown in FIG. 8. (1) off the internet as shown in FIG. 2. (2). Using a smart device (phone, tablet, or watch) as shown in FIG. 1 (1), a person as shown in FIG. 1 (3) takes photos or video as shown in FIG. 1 (1-3) of the skier's lower leg/legs and foot/feet as shown in FIG. 1 (2). These images as shown in FIG. 1 (1-3) are then converted to a 3-D image as shown in FIG. 2 (1).

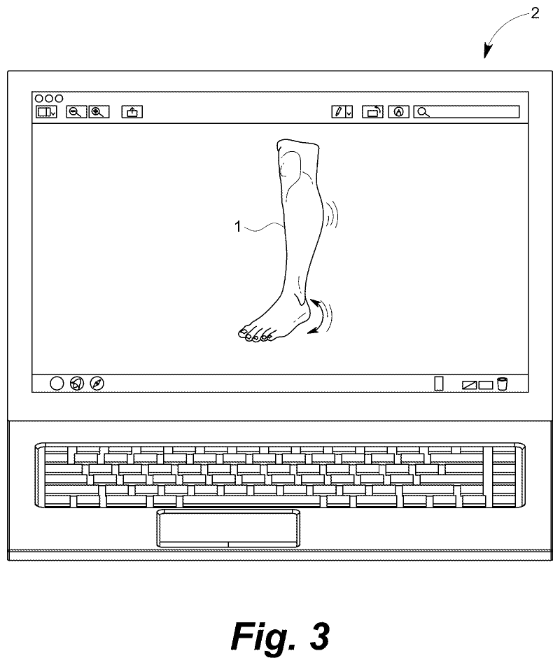

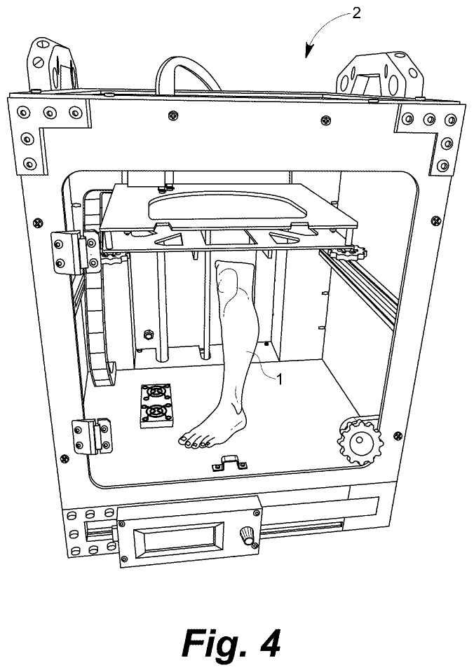

2. The 3-D image as shown in FIG. 2 (1) is then converted into a computer aided design known as a CAD as shown in FIG. 3 (2). The CAD image as shown in FIG. 3 (1) is then programed into a 3-D printer as shown in FIG. 4 (2). The 3-D Printer as shown in FIG. 4 (2) produces a replica of each of the skier's lower legs and feet as shown in FIG. 4 (1).

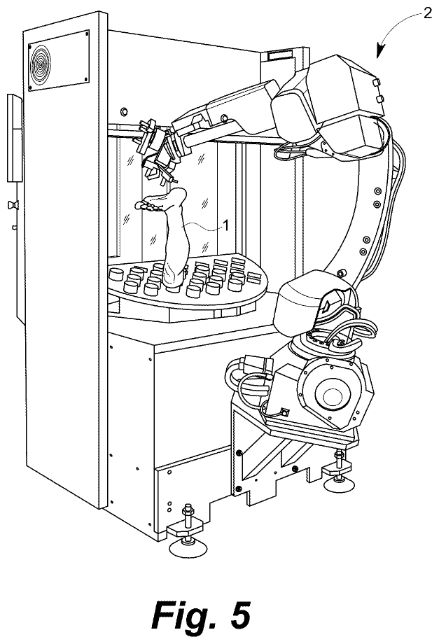

The CAD as shown in FIG. 3 can also be programmed into a computer numerical control robot known as a CNC as shown in FIG. 5 (2). The CNC machine as shown in FIG. 5 (2) is then used to produce a replica of each of the skier's lower legs and feet as shown in FIG. 5 (1).

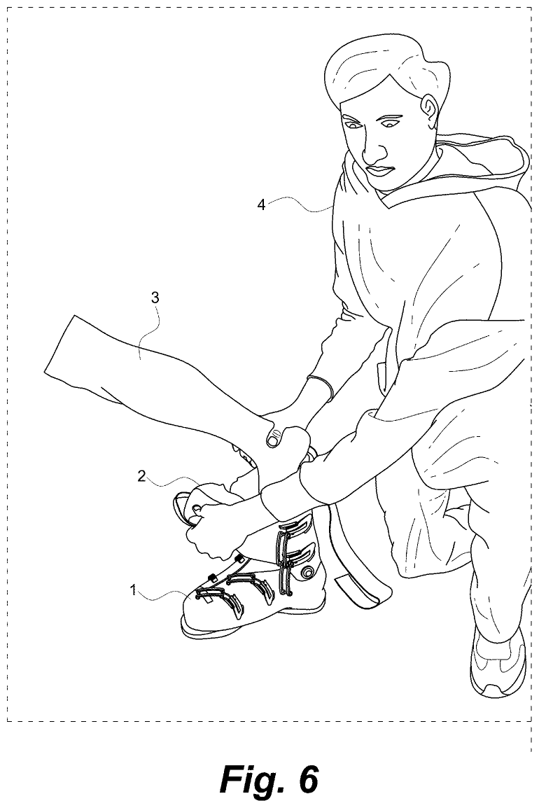

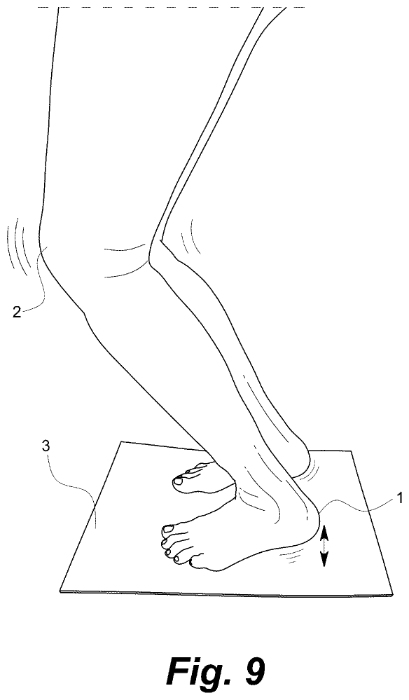

3. A person as shown in FIG. 6 (4) places the skier's replicated leg and foot as shown in FIG. 6 (3) into a heated liner as shown in FIG. 6 (2) and heated ski boot as shown in FIG. 6 (1). A person as shown in FIG. 7 (4) allows the heated liner and ski boot as shown in FIG. 7 (2-3) to mold to the replicated leg as shown in FIG. 7 (1). A heated ski footbed as shown in FIG. 8 (1) is applied to the replicated foot and leg as shown in FIG. 8 (2). The heated footbed as shown in FIG. 8 (1) cools to the shape of the replicated foot and leg as shown in FIG. 8 (2). The skier's ankle flex as shown in FIG. 9 is determined by a person as shown in FIG. 1 (3) taking a video or photos as shown in FIG. 1 (1) of a skier standing on a hard surface as shown in FIG. 9 (3). While flexing the knees forward, as shown in FIG. 9 (2), the point at which the skier's heels come upwards, as shown in FIG. 9 (1) off the hard surface as shown in FIG. 9 (3), determines the skier's ankle flex as shown in FIG. 9. The skier's ankle flex as shown in FIG. 9) is used to determine the ski boot flex FIG. 9) of the custom ski boot. FIG. 7 (3).

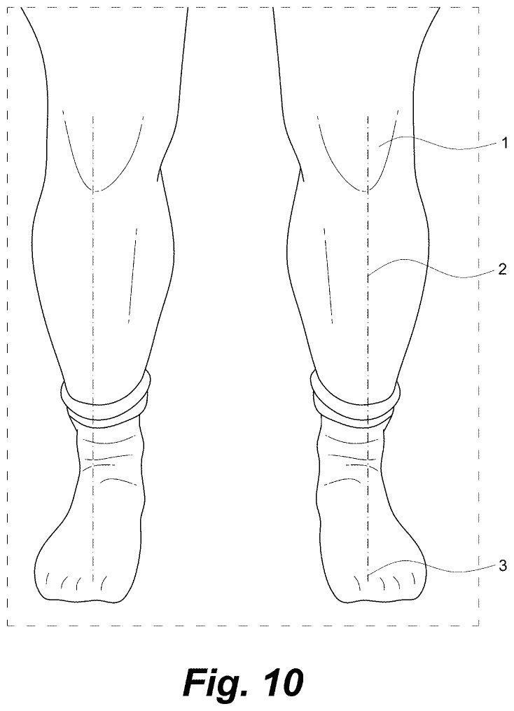

4. The skier's correct stance as shown in FIG. 10 is determined by a person as shown in FIG. 1 (3) taking a photo as shown in FIG. 1 (1) of a skier with bent knees as shown in FIG. 10-1. Using computer software as shown in FIG. 3. (2), a line as shown in FIG. 10 (2) is drawn from two thirds of the knee mass as shown in FIG. 10 (1) to the second toe as shown in FIG. 10. (3). This calculation as shown in FIG. 10 (1-3) is used to customize the ski boot as shown in FIG. 7 (3) so that the skier's foot and leg, while in the ski boot, as shown in FIG. 7. (1-3) have the correct stance as shown in FIG. 10.

1. Said process of taking a digital recording of said skier's lower legs and feet and converting said skier's lower legs and feet into a 3D image. This 3D image of said skier's lower legs and feet is then programmed into a computer assisted design known as a CAD. The CAD of said skier's lower legs and feet is then read by a 3D printer or a computer numerical control robot known as a CNC. The 3D printer or CNC robot is then used to produce said replicas of said skier's lower legs and feet. Said replicas of said skier's lower legs and feet are then used to produce a pair of custom ski footbeds and a pair of custom ski boots.
